(19) United States
(12) Patent Application Publication
(10) Pub. No.: US 2006/0154485 A1
(43) Pub. Date: Jul. 13, 2006

(54) Sacrificial layers comprising water-soluble compounds, uses and methods of production thereof

(76) Inventors: Bo Li, San Jose, CA (US); Joseph Kennedy, San Jose, CA (US)

Correspondence Address: BINGHAM, MCCUTCHEN LLP, THREE EMBARCADERO CENTER, 18 FLOOR, SAN FRANCISCO, CA, 94111-4067, US

(21) Appl. No.: 11/033,798

(22) Filed: Jan. 12, 2005

(51) Int. Cl. H01L 21/461

(52) U.S. Cl. 438/692

(57) ABSTRACT

Sacrificial composition and/or coating materials contemplated herein for use in semiconductor and electronic applications comprise at least one water-soluble compound and/or at least one water-soluble compound precursor and at least one solvent. Sacrificial materials and/or compositions may be produced by a method, comprising: a) providing at least one water-soluble compound and/or at least one water-soluble compound precursor, b) providing at least one solvent and c) blending the at least one water-soluble compound and/or precursor with the at least one solvent to form the sacrificial material and/or composition.

### FIELD OF THE SUBJECT MATTER

The present invention relates generally to sacrificial layers in semiconductor, optics, optoelectronics and electronic applications, materials and compositions for producing those sacrificial layers, methods of production and uses thereof.

### BACKGROUND OF THE SUBJECT MATTER

To meet the requirements for faster performance, the characteristic dimensions of features of integrated circuit devices have continued to be decreased. Manufacturing of devices with smaller feature sizes introduces new challenges in many of the processes conventionally used in semiconductor fabrication. Dual damascene patterning and via first trench last (VFTL) copper dual damascene patterning through a low dielectric constant (less than about 3) material or ultra low dielectric constant (less than about 2) material is one of these manufacturing methods. Two examples of dual damascene patterning and structures are shown in US Patent Publications 20040152296 and 20040150012—both assigned to Texas Instruments. One of the problems with this type of patterning is the selective removal of the sacrificial fill material from the low dielectric constant materials. Selective removal of sacrificial layers can also present problems in other types of devices, such as MEMS (microelectromechanical systems) devices, optics and optoelectronics-based devices or devices that contain these systems.

Photoresists, anti-reflective coatings and/or sacrificial materials can have substandard or unacceptable etch selectivity or stripping selectivity. Poor etch selectivity and/or stripping selectivity can lead to low etch rates for the film and can also lead to poor transfer of critical dimensions from the printing step(s) through the etch step(s). Attempts have been made at improving the etch rate by providing highly absorbing substances with substituent groups that can condense the silane compound to specific silane compounds, as seen in JP Patent Application No.: 2001-92122 published on Apr. 6, 2001. However, the etch selectivity obtained with these reactive compounds are not sufficient for most photoresists and anti-reflective coatings and require additional chemical reaction steps that may not be necessary.

In addition, photoresists and anti-reflective coatings often have difficulty with fill bias and voiding in via structures to the point where any planarization of the surface is severely compromised. Oftentimes, the two goals of increasing etch selectivity and minimizing fill bias and voiding directly conflict with one another, which is why it's important to review and understand the goals of each group of applications. Also, to sufficiently fill and planarize via arrays requires that a relatively thick anti-reflective coating exist. If the ARC coating is organic, such a thick coating will further compromise the accurate transfer of the as patterned critical dimension through the film stack.

Previous work has shown that Si—O fill materials (either UV absorbing or transparent) are the optimum materials platform, if the dielectric layer is Si—O based. And in order to improve the removal selectivity of the sacrificial fill material it can be chemically weakened relative to the dielectric material. A porogen or a high boiling solvent can be added to the fill material to weaken it; however, in order to achieve photoresist developer resistance the Si—O based fill material either needs to be baked to or at a sufficiently high temperature to ensure crosslinking or the porogen content needs to be lowered. Both of these methods designed to achieve photoresist developer resistance work with respect to strengthening the fill material, but the removal selectivity of the fill material is decreased.

Photoresists and anti-reflective coatings can also influence one another to the extent that the chemical properties of the anti-reflective coating and/or the resist material can lead the resist to “fall over” once a pattern has been developed into the resist. In other words, the patterned resist sidewall can't maintain an approximate 90-degree angle with respect to the anti-reflective coating after photoresist developing. Instead the resist will take on a 120-degree or an 80-degree angle with respect to the anti-reflective coating. These imperfections are also an indication that photoresist materials and anti-reflective coatings are not necessarily chemically, physically or mechanically compatible.

In developing anti-reflective coatings that can a) absorb strongly and uniformly in the ultraviolet spectral region; b) keep the resist material from “falling over” and expanding outside or contracting inside of the intended resist line and c) be impervious to photoresist developers and methods of production of spin-on glass anti-reflective coatings, Baldwin et al developed several anti-reflective coatings that are superior to conventional anti-reflective coatings, including those materials and coatings found in U.S. Pat. No. 6,268,457 issued on Jul. 31, 2001; U.S. Pat. No. 6,365,765 issued on Apr. 2, 2002; U.S. Pat. No. 6,368,400 issued on Apr. 9, 2002; U.S. patent application Ser. Nos. 09/491,166 filed Jan. 26, 2000; Ser. No. 10/012,651 filed Nov. 5, 2001; Ser. No. 10/012,649 filed Nov. 5, 2001; Ser. No. 10/001,143 filed Nov. 15, 2001; PCT Applications Serial Nos.: PCT/US00/15772 filed on Jun. 8, 2000; WO 02/06402 filed on Jul. 12, 2001; PCT/US01/45306 filed on Nov. 15, 2001; PCT Application Serial No.: PCT/US02/35101 filed on Oct. 31, 2002; European Patent Applications Serial No. 00941275.0 filed on Jun. 6, 2000; and 01958953.0 filed on Jul. 17, 2001, which are all commonly assigned and incorporated herein by reference in their entirety. However, with all of these materials, it would be beneficial to be able to modify the materials, coatings and films described therein to improve etch selectivity and/or stripping selectivity, improve the lithography performance and to minimize fill bias.

Another factor related to all types of sacrificial films, along with etch selectivity and compatibility issues, is the cost, storage and disposal of the stripping chemicals used to remove the sacrificial films and the resulting by-products. Many of the wet stripping chemicals used to remove sacrificial films are environmentally unsafe, costly to purchase, store and dispose of and/or both.

Therefore, a stripping chemistry that is compatible with sacrificial films, while being environmentally friendly, cost-efficient and easy to store would be ideal. In addition, sacrificial films and materials that a) can be modified to absorb strongly and uniformly in the ultraviolet spectral region, b) can keep the resist material from “falling over” and expanding outside or contracting inside of the intended resist line, c) would be impervious to photoresist developers and methods of production of the SOG anti-reflective coating described; d) can satisfy any goals of increasing etch selectivity and/or stripping selectivity and e) can satisfy any goals of minimizing fill bias and voiding in via structures; f) can form solutions that are stable and have a good shelf life; g) is compatible to various lithographic patterning techniques, including those that utilize ArF; h) can be applied to a surface by any suitable application method, such as spin-on coating or chemical vapor deposition (CVD); i) is capable of via fill and planarization; j) has good wet etch and dry etch rates; and k) can be utilized in a number of applications, components and materials, including logic applications and flash applications, in addition to 1) being compatible with a stripping chemistry that is environmentally friendly, cost-efficient and easy to store would also be ideal to produce and utilize.

### SUMMARY OF THE SUBJECT MATTER

Sacrificial composition and/or coating materials contemplated herein for use in semiconductor and electronic applications comprise at least one water-soluble compound and/or at least one water-soluble compound precursor and at least one solvent.

Sacrificial materials and/or compositions may be produced by a method, comprising: a) providing at least one water-soluble compound and/or at least one water-soluble compound precursor, b) providing at least one solvent and c) blending the at least one water-soluble compound and/or precursor with the at least one solvent to form the sacrificial material and/or composition.

### DESCRIPTION OF THE SUBJECT MATTER

A stripping chemistry that is compatible with some sacrificial films, while being environmentally friendly, cost-efficient and easy to store has been developed. In addition, sacrificial films and materials that a) can be modified to absorb strongly and uniformly in the ultraviolet spectral region, b) can keep the resist material from “falling over” and expanding outside or contracting inside of the intended resist line, c) would be impervious to photoresist developers and methods of production of the SOG anti-reflective coating described; d) can satisfy any goals of increasing etch selectivity and/or stripping selectivity and e) can satisfy any goals of minimizing fill bias and voiding in via structures; f) can form solutions that are stable and have a good shelf life; g) is compatible to various lithographic patterning techniques, including those that utilize ArF; h) can be applied to a surface by any suitable application method, such as spin-on coating or chemical vapor deposition (CVD); i) is capable of via fill and planarization; j) has good wet etch and dry etch rates; and k) can be utilized in a number of applications, components and materials, including logic applications and flash applications, in addition to 1) being compatible with a stripping chemistry that is environmentally friendly, cost-efficient and easy to store have also been produced, utilized and are described herein.

Sacrificial composition and/or coating materials contemplated herein for use in semiconductor and electronic applications comprise at least one water-soluble compound and/or at least one water-soluble compound precursor and at least one solvent. In other embodiments, sacrificial compositions and/or coating materials contemplated herein may comprise at least one absorbing compound and/or material and/or at least one material modification agent. The at least one material modification agent may include any compound or composition that can modify the coating material to improve the photolithographic, compatibility and/or physical quality of the resulting film or layered material, such as by improving the etch selectivity and/or stripping selectivity, by minimizing the fill bias, by facilitating removal and/or by improving the stability or shelf life of the material/composition. The at least one material modification agent may comprise at least one adhesion promoter, at least one pH tuning agent, at least one porogen, at least one leveling agent, at least one high-boiling solvent, at least one crosslinking agent, at least one catalyst, at least one capping agent and/or combinations thereof. Surprisingly, at least in some embodiments, the material modification agent (such as the at least one adhesion promoter) comprises a compound or composition that is conventionally viewed as a poisoning agent for lithography and thus avoided by the industry, but its use in the embodiments described herein improves the adhesion of the lithography composition without poisoning the composition. Contemplated material modification agents, such as those disclosed in PCT Applications PCT/US02/36327 filed on Nov. 12, 2002; PCT/US03/36354 filed on Nov. 12, 2003 and in U.S. application Ser. No. 10/717,028 filed on Nov. 18, 2003, which are all commonly-owned by Honeywell International Inc. and are incorporated herein in their entirety.

Sacrificial materials and/or compositions contemplated herein may be produced by a method, comprising: a) providing at least one water-soluble compound and/or at least one water-soluble compound precursor, b) providing at least one solvent and c) blending the at least one water-soluble compound and/or precursor with the at least one solvent to form the sacrificial material and/or composition. In some embodiments, the sacrificial materials and/or compositions may be utilized as etch stops or hard masks. In other embodiments, the sacrificial materials and/or compositions may be utilized as via fill or planarization materials. In yet other contemplated embodiments at least one absorbing moiety and/or compound may be provided and may be either reacted with the at least one water-soluble compound and/or precursor to form an absorbing water-soluble compound or blended with the sacrificial composition and/or material. And in yet other embodiments, at least one material modification agent may be provided and blended with the sacrificial composition and/or material.

The at least one water-soluble compound, the at least one water-soluble compound precursor, the at least one solvent, the at least one material modification agent and/or the at least one absorbing moiety and/or compound may be provided by any suitable method, including a) buying at least some of the at least one water-soluble compound, the at least one water-soluble compound precursor, the at least one solvent, the at least one material modification agent and/or the at least one absorbing moiety and/or compound from a supplier; b) preparing or producing at least some of the at least one water-soluble compound, the at least one water-soluble compound precursor, the at least one solvent, the at least one material modification agent and/or the at least one absorbing moiety and/or compound in house using chemicals provided by another source and/or c) preparing or producing at least some of the at least one water-soluble compound, the at least one water-soluble compound precursor, the at least one solvent, the at least one material modification agent and/or the at least one absorbing moiety and/or compound in house using chemicals also produced or provided in house or at the location.

As mentioned, contemplated sacrificial compositions and/or coating materials contemplated herein for use in semiconductor and electronic applications may comprise at least one water-soluble compound, including water-soluble polymers and polymer salts (both metal and non-metal) and/or at least one water-soluble precursor, and at least one solvent. As used herein, the phrase “water-soluble compound” means any substance, compound or moiety that swells or dissolves in water at normal temperature. These compounds can be natural compounds, semisynthetic compounds or synthetic compounds. Traditionally, these water-soluble compounds have been used as thickeners, adhesives, coatings, food additives, textile sizing, etc. (see Hawley's Condensed Chemical Dictionary, 12^{th} Edition, Edited by Richard J. Lewis, Sr.) As used herein, the phrase “water-soluble compound precursor” means those compounds or moieties that can form water-soluble compounds upon reaction with each other or other moieties, including other water-soluble compounds or water-soluble compound precursors. Water-soluble compound precursors may, in and of themselves, be water-soluble. Also, as used herein, the term “water” means pure, deionized and/or tap water. Water, as used herein, is contemplated in some embodiments hard water, soft water or water that contains low levels of sodium and/or other contaminants—such as those found in tap water.

As mentioned, water-soluble compounds and water-soluble compound precursors may comprise any suitable compound, as long as it meets the above definition. Water-soluble compounds and water-soluble compound precursors may comprise polyacrylamides and modified polyacrylamides, poly(acrylic acid), salts comprising poly(acrylic acid), poly(2-ethyl-2-oxazoline), polygalacturonic acid and salts thereof, poly(methacrylic acid) and salts thereof, poly(vinyl alcohol), alpha-cellulose, hydroxyethyl cellulose, N-vinylpyrrolidone/vinyl acetate copolymer and combinations thereof.

As mentioned earlier, contemplated materials comprise at least one absorbing compound and/or material. Many naphthalene-, phenanthrene- and anthracene-based compounds have significant absorption at 248 nm and below. Benzene-based, equivalently termed here phenyl-based, compounds have significant absorption at wavelengths shorter than 200 nm. While these naphthalene-, anthracene-, phenanthrene- and phenyl-based compounds are frequently referred to as dyes, the term absorbing compound is used here because the absorptions of these compounds are not limited to wavelengths in the visible region of the spectrum. However, not all such absorbing compounds can be incorporated into inorganic-based materials for use as anti-reflective coating materials. Preferred absorbing compounds suitable for use have a definable absorption peak centered around wavelengths such as 248 nm, 193 nm, 157 nm or other ultraviolet wavelengths, such as 365 nm, that may be used in photolithography. It is contemplated that a suitable “definable absorption peak” is one that is at least 0.5 nm in width, wherein width is calculated by those methods commonly known in the art of photolithography. In more preferred embodiments, the definable absorption peak is at least 1 nm in width. In even more preferred embodiments, the definable absorption peak is at least 5 nm in width. In most preferred embodiments, the definable absorption peak is at least 10 nm in width. Suitable absorbing compounds are those mentioned above, and specifically defined and taught in U.S. Pat. Nos. 6,268,457, 6,506,497, 6,365,765, 6,368,400, 6,605,362, U.S. application Ser. Nos.: 10/001,143, 10/076,846, 10/012,649, 10/300,357, 10/428,807, PCT Application Serial Nos.: PCT/US00/15772, PCT/US02/35101, PCT/US01/43831, PCT/US01/22232, PCT/US02/36327, PCT/US03/36354 and related foreign applications and patents, which are commonly-owned by Honeywell International Inc. and are incorporated herein in their entirety by reference.

In contemplated embodiments, the addition of the material modification agent will improve at least one of the etching rate, the shelf life, the ability of the composition to planarize and/or via fill, or the measurable lithography properties by at least 25% over those same compositions without the additional material modification agent. In other contemplated embodiments, the addition of the material modification agent will improve at least one of the etching rate, the shelf life, the ability of the composition to planarize and/or via fill, or the measurable lithography properties by at least 50% over those same compositions without the additional material modification agent. In yet other contemplated embodiments, the addition of the material modification agent will improve at least one of the etching rate, the shelf life, the ability of the composition to planarize and/or via fill, or the measurable lithography properties by at least 75% over those same compositions without the additional material modification agent.

Sacrificial compositions and/or materials described herein may be coupled, applied or dispensed onto any suitable surface by any suitable method or apparatus, in order to produce a layer or film that is at least partially sacrificial during or after the application of water. As used herein, the term “coupled” means that the surface and layer or two layers are physically attached to one another or there's a physical attraction between two parts of matter or components, including bond forces such as covalent and ionic bonding, and non-bond forces such as Van der Waals, electrostatic, coulombic, hydrogen bonding and/or magnetic attraction. Also, as used herein, the term coupled is meant to encompass a situation where the surface and layer or two layers are directly attached to one another, but the term is also meant to encompass the situation where the surface and the layer or plurality of layers are coupled to one another indirectly—such as the case where there's an adhesion promoter layer between the surface and layer or where there's another layer altogether between the surface and layer or plurality of layers.

The terms “layer” and “film” differ in this application in that the term “film” refers to at least a partially cured layer. Also, in some embodiments, the layer or film may be cured or further cured in order to convert the sacrificial layer and/or film into a non-sacrificial film.

The phrase “at least partially sacrificial” means that the water-soluble film or layer is at least partially removed during or after the application of water. There may be portions of the sacrificial layer or film that are masked or otherwise produced such that they are not exposed to or do not react with water. For example, a water-soluble sacrificial film or layer can be formed that is partially masked. The exposed portions of the film or layer may be treated in such a way as to apply another layer of material or apply a curing treatment. These treatments may be designed to make the exposed portions of the layer or film—that were otherwise sacrificial, not sacrificial when exposed to water. Therefore, when the entire film or layer is exposed to water, only portions of the layer or film are soluble.

Typical solvents are also those solvents that are able to at least in part solvate the water-soluble compounds or compositions without significantly affecting the ability of the water-soluble compound or possibly the precursor to remain water-soluble. Contemplated solvents include any suitable pure or mixture of organic or inorganic molecules that are volatilized at a desired temperature, such as the critical temperature, or that can facilitate any of the above-mentioned design goals or needs. The solvent may also comprise any suitable pure or mixture of polar and non-polar compounds. As used herein, the term “pure” means that component that has a constant composition. For example, pure water is composed solely of H₂O. As used herein, the term “mixture” means that component that is not pure, including salt water. As used herein, the term “polar” means that characteristic of a molecule or compound that creates an unequal charge, partial charge or spontaneous charge distribution at one point of or along the molecule or compound. As used herein, the term “non-polar” means that characteristic of a molecule or compound that creates an equal charge, partial charge or spontaneous charge distribution at one point of or along the molecule or compound.

In other contemplated embodiments, the solvent or solvent mixture may comprise those solvents that are not considered part of the hydrocarbon solvent family of compounds, such as ketones, such as acetone, diethyl ketone, methyl ethyl ketone and the like, alcohols, esters, ethers and amines. In yet other contemplated embodiments, the solvent or solvent mixture may comprise a combination of any of the solvents mentioned herein.

In contemplated embodiments, the solvent and/or solvent mixutre comprises water, ethanol, propanol, acetone, ethylene oxide, ethylene glycol, glycerol, lactic acid, dioxane, DMF, methylene chloride, THF, diluted acids, such as dilute aqueous sodium hydroxide, glycols, diethylenetriamine, DMAC, DMSO, ethylenediamine, formalin, formic acid, phenol, benzene, toluene, ethers, cyclohexanone, butyrolactone, methylethylketone, anisole and combinations thereof.

In some contemplated embodiments, the solvent or solvent mixture (comprising at least two solvents) comprises those solvents that are considered part of the hydrocarbon family of solvents. Hydrocarbon solvents are those solvents that comprise carbon and hydrogen. It should be understood that a majority of hydrocarbon solvents are non-polar; however, there are a few hydrocarbon solvents that could be considered polar. Hydrocarbon solvents are generally broken down into three classes: aliphatic, cyclic and aromatic. Aliphatic hydrocarbon solvents may comprise both straight-chain compounds and compounds that are branched and possibly crosslinked, however, aliphatic hydrocarbon solvents are not considered cyclic. Cyclic hydrocarbon solvents are those solvents that comprise at least three carbon atoms oriented in a ring structure with properties similar to aliphatic hydrocarbon solvents. Aromatic hydrocarbon solvents are those solvents that comprise generally three or more unsaturated bonds with a single ring or multiple rings attached by a common bond and/or multiple rings fused together. Contemplated hydrocarbon solvents include toluene, xylene, p-xylene, m-xylene, mesitylene, solvent naphtha H, solvent naphtha A, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosine, isobutylbenzene, methylnaphthalene, ethyltoluene, ligroine. Particularly contemplated solvents include, but are not limited to, pentane, hexane, heptane, cyclohexane, benzene, toluene, xylene and mixtures or combinations thereof.

Substrates contemplated herein may comprise any desirable substantially solid material. Particularly desirable substrate layers would comprise films, glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimide. In more preferred embodiments, the substrate comprises a material common in the packaging and circuit board industries such as silicon, copper, glass, and another polymer.

As mentioned, contemplated sacrificial layers or films of the compositions described herein may be formed by solution techniques such as spraying, rolling, dipping, spin coating, flow coating, chemical vapor deposition (CVD), or casting, with spin coating being preferred for microelectronics.

For chemical vapor deposition (CVD), the composition is placed into an CVD apparatus, vaporized, and introduced into a deposition chamber containing the substrate to be coated. Vaporization may be accomplished by heating the composition above its vaporization point, by the use of vacuum, or by a combination of the above. Generally, vaporization is accomplished at temperatures in the range of 50° C.-300° C. under atmospheric pressure or at lower temperature (near room temperature) under vacuum.

Three types of CVD processes exist: atmospheric pressure CVD (APCVD), low pressure CVD (LPCVD), and plasma enhanced CVD (PECVD). Each of these approaches had advantages and disadvantages. APCVD devices operate in a mass transport limited reaction mode at temperatures of approximately 400° C. In mass-transport limited deposition, temperature control of the deposition chamber is less critical than in other methods because mass transport processes are only weakly dependent on temperature. As the arrival rate of the reactants is directly proportional to their concentration in the bulk gas, maintaining a homogeneous concentration of reactants in the bulk gas adjacent to the wafers is critical.

Thus, to insure films of uniform thickness across a wafer, reactors that are operated in the mass transport limited regime must be designed so that all wafer surfaces are supplied with an equal flux of reactant. The most widely used APCVD reactor designs provide a uniform supply of reactants by horizontally positioning the wafers and moving them under a gas stream.

In contrast to APCVD reactors, LPCVD reactors operate in a reaction rate-limited mode. In processes that are run under reaction rate-limited conditions, the temperature of the process is an important parameter. To maintain a uniform deposition rate throughout a reactor, the reactor temperature must be homogeneous throughout the reactor and at all wafer surfaces. Under reaction rate-limited conditions, the rate at which the deposited species arrive at the surface is not as critical as constant temperature. Thus, LPCVD reactors do not have to be designed to supply an invariant flux of reactants to all locations of a wafer surface.

Under the low pressure of an LPCVD reactor, for example, operating at medium vacuum (30-250 Pa or 0.25-2.0 torr) and higher temperature (550-600° C.), the diffusivity of the deposited species is increased by a factor of approximately 1000 over the diffusivity at atmospheric pressure. The increased diffusivity is partially offset by the fact that the distance across which the reactants must diffusive increases by less than the square root of the pressure. The net effect is that there is more than an order of magnitude increase in the transport of reactants to the substrate surface and by-products away from the substrate surface.

LPCVD reactors are designed in two primary configurations: (a) horizontal tube reactors; and (b) vertical flow isothermal reactors. Horizontal tube, hot wall reactors are the most widely used LPCVD reactors in VLSI processing. They are employed for depositing poly-Si, silicon nitride, and undoped and doped SiO₂ films. They find such broad applicability primarily because of their superior economy, throughput, uniformity, and ability to accommodate large diameter, e.g., 150 mm, wafers.

The vertical flow isothermal LPCVD reactor further extends the distributed gas feed technique so that each wafer receives an identical supply of fresh reactants. Wafers are again stacked side by side, but are placed in perforated-quartz cages. The cages are positioned beneath long, perforated, quartz reaction-gas injector tubes, one tube for each reactant gas. Gas flows vertically from the injector tubes, through the cage perforations, past the wafers, parallel to the wafer surface and into exhaust slots below the cage. The size, number, and location of cage perforations are used to control the flow of reactant gases to the wafer surfaces. By properly optimizing cage perforation design, each wafer may be supplied with identical quantities of fresh reactants from the vertically adjacent injector tubes. Thus, this design may avoid the wafer-to-wafer reactant depletion effects of the end-feed tube reactors, requires no temperature ramping, produces highly uniform depositions, and reportedly achieves low particulate contamination.

The third major CVD deposition method is PECVD. This method is categorized not only by pressure regime, but also by its method of energy input. Rather than relying solely on thermal energy to initiate and sustain chemical reactions, PECVD uses an rf-induced glow discharge to transfer energy into the reactant gases, allowing the substrate to remain at a lower temperature than in APCVD or LPCVD processes. Lower substrate temperature is the major advantages of PECVD, providing film deposition on substrates not having sufficient thermal stability to accept coating by other methods. PECVD may also enhance deposition rates over those achieved using thermal reactions. Moreover, PECVD may produce films having unique compositions and properties. Desirable properties such as good adhesion, low pinpole density, good step coverage, adequate electrical properties, and compatibility with fine-line pattern transfer processes, have led to application of these films in VLSI.

PECVD requires control and optimization of several deposition parameters, including RF power density, frequency, and duty cycle. The deposition process is dependent in a complex and interdependent way on these parameters, as well as on the usual parameters of gas composition, flow rates, temperature, and pressure. Furthermore, as with LPCVD, the PECVD method is surface reaction limited, and adequate substrate temperature control is thus necessary to ensure uniform film thickness.

CVD systems usually contain the following components: gas sources, gas feed lines, mass-flow controllers for metering the gases into the system, a reaction chamber or reactor, a method for heating the wafers onto which the film is to be deposited, and in some types of systems, for adding additional energy by other means, and temperature sensors. LPCVD and PECVD systems also contain pumps for establishing the reduced pressure and exhausting the gases from the chamber.

Additives can also be used to enhance or impart particular target properties, as is conventionally known in the polymer art, including stabilizers, flame retardants, pigments, plasticizers, surfactants, and the like. Compatible or non-compatible polymers can be blended in to give a desired property. Adhesion promoters can also be used. Such promoters are typified by hexamethyldisilazane, which can be used to interact with available hydroxyl functionality that may be present on a surface, such as silicon dioxide, that was exposed to moisture or humidity. Polymers for microelectronic applications desirably contain low levels (generally less than 1 ppm, preferably less than 10 ppb) of ionic impurities, particularly for dielectric interlayers. For example, where the low dielectric constant material is exposed to mechanical stress, softeners or other protective agents may be added. In other cases where the dielectric material is placed on a smooth surface, adhesion promoters may advantageously employed. In still other cases, the addition of detergents or antifoam agents may be desirable.

In some embodiments, the sacrificial layers or films (or at least one of the sacrificial layers or films if there are multiple layers) may comprise a plurality of voids and/or pores. This plurality of voids can also be expressed by using the phrase “nanoporous layer” or “ultrananoporous layer”. As used herein, the term “nanoporous layer” refers to any suitable low dielectric material (i.e. ≦3.0) that is composed of a plurality of voids and a non-volatile component. As used herein, the term “substantially” means a desired component is present in a layer at a weight percent amount greater than 51%. A layered material herein described also comprises: a) a dielectric material having a plurality of pores, wherein each pore has a pore diameter; and b) a layer comprising a plurality of particles, wherein the particles have a particle size that is larger than the pore diameter.

Incorporating or introducing porogens into the dielectric materials can form the plurality of pores and/or voids. At least one porogen may be added to the dielectric material and/or layer. The pores or voids may be formed as a result of structural rearrangement or loss of material such that a pore or void or increase in free volume is left behind.

As used herein, the term “pore” includes voids and cells in a material and any other term meaning space. The term “pore” may also include a differential in material density wherein the free volume has been increased (“porous nature” has been introduced). Appropriate gases include relatively pure gases and mixtures thereof. Air, which is predominantly a mixture of N₂ and O₂ is commonly distributed in the pores, but pure gases such as nitrogen, helium, argon, CO₂ or CO are also contemplated. Pores are typically spherical but may alternatively or additionally include tubular, lamellar, discoidal, voids having other shapes, or a combination of the preceding shapes and may be open or closed. The term “porogen” as used herein may have a variety of mechanisms available to form the pore but in general is a material, which upon removal, leaves behind either a “pore” or a “void” or a material that can rearrange to create a “pore” or “void”. In one embodiment, a porogen is a decomposable material that is radiation, thermally, chemically or moisture decomposable, degradable, depolymerizable or otherwise capable of breaking down and includes solid, liquid or gaseous material.

Contemplated polymer materials, coating solutions and films can be utilized are useful in the fabrication of a variety of electronic devices, micro-electronic devices, optics or optoelectronic-based devices, semiconductor integrated circuits and various layered materials for electronic and semiconductor components, including hardmask layers, dielectric layers, etch stop layers and buried etch stop layers. These polymer materials, coating solutions and films are quite compatible with other materials that might be used for layered materials and devices, such as adamantane-based compounds, diamantane-based compounds, silicon-core compounds, organic dielectrics, and nanoporous dielectrics. Compounds that are considerably compatible with the coating materials, coating solutions and films contemplated herein are disclosed in PCT Application PCT/US01/32569 filed Oct. 17, 2001; PCT Application PCT/US01/50812 filed Dec. 31, 2001; U.S. application Ser. No. 09/538,276; U.S. application Ser. No. 09/544,504; U.S. application Ser. No. 09/587,851; U.S. Pat. No. 6,214,746; U.S. Pat. No. 6,171,687; U.S. Pat. No. 6,172,128; U.S. Pat. No. 6,156,812, U.S. Application Ser. No. 60/350,187 filed Jan. 15, 2002; and U.S. 60/347,195 filed Jan. 8, 2002, which are all incorporated herein by reference in their entirety.

Coating materials contemplated herein may also be coupled to anti-reflective coating materials that are designed to a) absorb strongly and uniformly in the ultraviolet spectral region; b) keep the resist material from “falling over” and expanding outside or contracting inside of the intended resist line and/or c) be impervious to photoresist developers and methods of production of anti-reflective coatings. Baldwin et al. have developed several anti-reflective coatings that are superior to conventional anti-reflective coatings, including those materials and coatings found in U.S. Pat. No. 6,268,457 issued on Jul. 31, 2001; U.S. Pat. No. 6,365,765 issued on Apr. 2, 2002; U.S. Pat. No. 6,368,400 issued on Apr. 9, 2002; U.S. patent application Ser. Nos. 09/491,166 filed Jan. 26, 2000; Ser. No. 10/012,651 filed Nov. 5, 2001; Ser. No. 10/012,649 filed Nov. 5, 2001; Ser. No. 10/001,143 filed Nov. 15, 2001; PCT Applications Serial Nos.: PCT/US00/15772 filed on Jun. 8, 2000; WO 02/06402 filed on Jul. 12, 2001; PCT/US01/45306 filed on Nov. 15, 2001; Pending PCT Application filed on Oct. 31, 2002 (Ser. No. ______); Pending PCT Application PCT/US02/36327 filed on Nov. 12, 2002; European Patent Applications Serial No. 00941275.0 filed on Jun. 6, 2000; and 01958953.0 filed on Jul. 17, 2001, which are all commonly assigned and incorporated herein by reference in their entirety. However, with all of these materials, it would be beneficial to be able to modify the materials, coatings and films described therein to improve etch selectivity and/or stripping selectivity and to minimize fill bias.

The compounds, coatings, films, materials and the like described herein may be used to become a part of, form part of or form an electronic component and/or semiconductor component. As used herein, the term “electronic component” also means any device or part that can be used in a circuit to obtain some desired electrical action. Electronic components contemplated herein may be classified in many different ways, including classification into active components and passive components. Active components are electronic components capable of some dynamic function, such as amplification, oscillation, or signal control, which usually requires a power source for its operation. Examples are bipolar transistors, field-effect transistors, and integrated circuits. Passive components are electronic components that are static in operation, i.e., are ordinarily incapable of amplification or oscillation, and usually require no power for their characteristic operation. Examples are conventional resistors, capacitors, inductors, diodes, rectifiers and fuses.

Electronic components contemplated herein may also be classified as conductors, semiconductors, or insulators. Here, conductors are components that allow charge carriers (such as electrons) to move with ease among atoms as in an electric current. Examples of conductor components are circuit traces and vias comprising metals. Insulators are components where the function is substantially related to the ability of a material to be extremely resistant to conduction of current, such as a material employed to electrically separate other components, while semiconductors are components having a function that is substantially related to the ability of a material to conduct current with a natural resistivity between conductors and insulators. Examples of semiconductor components are transistors, diodes, some lasers, rectifiers, thyristors and photosensors.

Electronic components contemplated herein may also be classified as power sources or power consumers. Power source components are typically used to power other components, and include batteries, capacitors, coils, and fuel cells. Power consuming components include resistors, transistors, integrated circuits (ICs), sensors, and the like.

Still further, electronic components contemplated herein may also be classified as discreet or integrated. Discreet components are devices that offer one particular electrical property concentrated at one place in a circuit. Examples are resistors, capacitors, diodes, and transistors. Integrated components are combinations of components that that can provide multiple electrical properties at one place in a circuit. Examples are integrated circuits in which multiple components and connecting traces are combined to perform multiple or complex functions such as logic.

The present composition may be used as an interlayer dielectric in an interconnect associated with a single integrated circuit (“IC”) chip. An integrated circuit chip would typically have on its surface a plurality of layers of the instant composition and multiple layers of metal conductors. It may also include regions of the present composition between discrete metal conductors or regions of conductor in the same layer or level of an integrated circuit.

In application of the instant polymers to ICs, a solution of the present composition is applied to a semiconductor wafer using conventional wet coating processes as, for example, spin coating; other well known coating techniques such as spray coating, flow coating, or dip coating may be employed in specific cases. In the spin coating process, the organosiloxane resin solution prepared in the manner described above is dispensed onto a wafer at or near its center. In some embodiments, the wafer will remain stationary during the dispense cycle, while in some embodiments, the wafer will turn or spin at a relatively low speed, typically at least about 200 revolutions per minute (rpm). Optionally, the dispense cycle may be followed by a short rest period and then additional spins, hereinafter referred to as thickness spins, generally between approximately 500 and 3000 rpm, although other spin speeds may be used, as appropriate. As an illustration, a cyclohexanone solution of the present composition is spin-coated onto a substrate having electrically conductive components fabricated therein and the coated substrate is then subjected to thermal processing. The present composition may be used in subtractive metal (such as aluminum and aluminum/tungsten) processing and dual damascene (such as copper) processing. An exemplary formulation of the instant composition is prepared by dissolving the present composition in cyclohexanone solvent under ambient conditions with strict adherence to a clean-handling protocol to prevent trace metal contamination in any conventional apparatus having a non-metallic lining.

An illustration of the use of the polymer solutions described herein follows. Application of the instant compositions and casting solutions onto planar or topographical surfaces or substrates may be carried out by using any conventional apparatus, preferably a spin coater, because the compositions used herein have a controlled viscosity suitable for such a coater. Complete evaporation of the solvent by any suitable means, such as simple air drying during spin coating, by exposure to an ambient environment, or by heating on a hot plate or a plurality of hot plates up to 350° C., may be employed. The substrate may have on it at least one layer of the present composition. Further curing may be achieved by a hot temperature, i.e, greater than 300° C., hot plate or furnace. In addition to furnace or hot plate curing, the present compositions may also be cured by exposure to ultraviolet radiation, microwave radiation, or electron beam radiation as taught by commonly assigned patent publication PCT/US96/08678; PCT/US00/28689 (WO 01/29052); and PCT/US00/28738 (WO 01/29141); and U.S. Pat. Nos. 6,042,994; 6,080,526; 6,177,143; and 6,235,353, which are incorporated herein by reference in their entireties. The present compositions may also be subjected to ultraviolet radiation, microwave radiation, or electron beam radiation to achieve certain desirable film properties.

After application of the present composition to an electronic topographical substrate, the coated structure is subjected to a bake and cure thermal process at increasing temperatures ranging from about 50° C. up to about 450° C. to polymerize the coating. The preferred curing temperature is at least about 130° C. Generally, it is preferred that curing is carried out at temperatures of from about 350° C. to about 425° C. Curing may be carried out in a conventional curing chamber such as an electric furnace, hot plate, and the like and is generally performed in an inert (non-oxidizing) atmosphere (nitrogen) in the curing chamber. Any non-oxidizing or reducing atmospheres (eg. argon, helium, hydrogen, and nitrogen processing gases) may be used in the practice of the present invention. One advantage of the present composition is that it has minimal weight loss during curing.

As indicated earlier, the present coating may act as an interlayer and be on top of or covered by other organic or inorganic coatings, such as other dielectric (SiO₂) coatings, SiO₂ modified ceramic oxide layers, silicon containing coatings, silicon carbon containing coatings, silicon nitrogen containing coatings, silicon-nitrogen-carbon containing coatings, diamond like carbon coatings, titanium nitride coatings, tantalum nitride coatings, tungsten nitride coatings, aluminum coatings, copper coatings, tantalum coatings, organosiloxanes coatings, organosilicon glass coatings, and fluorinated silicon glass coatings. Such multilayer coatings are taught in U.S. Pat. No. 4,973,526, which is incorporated herein by reference. And, as amply demonstrated, the present compositions prepared in the instant process may be readily formed as interlined dielectric layers between adjacent conductor paths on fabricated electronic or semiconductor substrates.

A semiconductor device comprising a film of the present composition typically has a second film adjacent to the first film. This second film may be an inorganic or organic material. A preferred organic material is an aromatic or aliphatic hydrocarbon and more preferably, an adamantane or diamantane based material is used. Examples of useful materials for the second film include but are not limited to those disclosed in International Publication WO 00/31183 published Jun. 2, 2000 and our pending patent applications Serial PCT/US01/22204 filed Oct. 17, 2001; PCT/US01/50182 filed Dec. 31, 2001; No. 60/345,374 filed Dec. 31, 2001; No. 60/347,195 filed Jan. 8, 2002; No. 60/350,187 filed Jan. 15, 2002; commonly assigned U.S. Pat. Nos. 6,126,733; 5,115,082; 5,986,045; and 6,143,855; and commonly assigned International Patent Publications WO 02/29052 published Apr. 26, 2001; and WO 01/29141 published Apr. 26, 2001.

The present composition may be used in a desirable all spin-on stacked film as taught by Michael E. Thomas, “Spin-On Stacked Films for Low k_{eff} Dielectrics”, Solid State Technology (July 2001), incorporated herein in its entirety by reference.

### EXAMPLES

### Example 1

Table 1 below shows the constituents of several contemplated sacrificial materials and/or compositions, including the solvent(s) utilized to form the sacrificial materials and/or compositions.

| WATER-SOLUBLE | PHYSICAL FORM | | | |
|---|---|---|---|---|
| COMPOUNDS | (% = BY VOLUME) | MW | TG | SOLVENTS(S) |
| polyacrylamide | 50% in water | 1500 | 165 | ethylene glycol, glycerol, |
| | | | | lactic acid, water |
| polyacrylamide, carboxyl | powder | 200,000 | | ethylene glycol, glycerol, |
| modified, high carboxyl content | | | | lactic acid, water |
| poly(acrylic acid) | 63% in water | 2000 | | dioxane, methanol, |
| | | | | ethanol, water |
| poly(acrylic acid), sodium salt | powder | 6000 | | water |
| poly(2-ethyl-2-oxazoline) | chunks | 5000 | 70 | acetone, DMF, ethanol, |
| | | | | MEK, methanol, methylene |
| | | | | chloride, THF, water |
| polygalacturonic acid | powder | | 60 | water |
| polygalacturonic acid, | powder | | | water |
| lithium salt | | | | |
| polygalacturonic acid, | powder | 25-50000 | 42 | diluted acids, water |
| methyl ester | | | | |
| poly(methacrylic acid) | powder | 180000 | 28 | dilute aqueous sodium |
| | | | | hydroxide, methanol, water |
| poly(methyacrylic acid), | 30% in water | 6500 | | water |
| sodium salt | | | | |
| poly(vinyl alcohol), | granular | 2000 | 235 | glycerol(hot), |
| 78% hydrolyzed | | | | glycols(hot), water |
| poly(vinyl alcohol), | granular | 3000 | 200 | glycerol(hot), |
| 88% hydrolyzed | | | | glycols(hot), water |
| alpha-cellulose | powder | | | water |
| hydroxyethyl cellulose | powder | | >141 | diethylenetriamine, |
| | | | | DMAC, DMF, DMSO, |
| | | | | ethylenediamine, |
| | | | | formalin, formic acid, |
| | | | | phenol, water |
| N-vinylpyrrolidone/vinyl | 50% in IPA | 2000 | | THF, water |
| acetate copolymer | (60% VP) | | | |

### Example 2

Table 2 below shows the constituents of several contemplated sacrificial materials and/or compositions, including the solvent(s) utilized to form the sacrificial materials and/or compositions, and wet strip rate in different solvents including water.

| | | DESCRIPTIONS | | |
|---|---|---|---|---|
| | | 4 g PVA/ | 4 g PVA/ | 4 g PVA/ |
| | | 4 g H₂O | 4 g H₂O | 4 g H₂O |
| | | 130/250° C. | 130/200° C. | 130/150° C. |
| | | bake, 60 sec. | bake, 60 sec. | bake, 60 sec. |
| INITIAL FILM THICKNESS | | 2335 | 3152 | 3307 |
| (ANGSTROMS) | | | | |
| METRICS | | ER (A/min) | ER (A/min) | ER (A/min) |
| PGMEA @ | 1 min | 522 | >3152 | >3307 |
| 21° C. | 5 min | 529 | | |
| DI Water @ | 2 min | 331 | >1576 | >1654 |
| 21° C. | 1 min | 438 | >3152 | >3307 |
| DI Water @ | 2 min | 353 | >1576 | >1657 |
| 50° C. | 1 min | 723 | >3152 | >3307 |

ER = Etch Rate

### Example 3

Table 3 below shows the constituents of several contemplated sacrificial materials and/or compositions, including the solvent(s) utilized to form the sacrificial materials and/or compositions, and wet strip rate in different solvents including water.

| | | DESCRIPTIONS | | |
|---|---|---|---|---|
| | | 10 g PVP/ | 10 g PVP/ | 10 g PVP/ |
| | | 90 g EtOH | 90 g EtOH | 90 g EtOH |
| | | 130/250° C. | 130/200° C. | 130/150° C. |
| | | bake, 60 sec. | bake, 60 sec. | bake, 60 sec. |
| INITIAL FILM THICKNESS | | 5112 | 5166 | 5331 |
| (ANGSTROMS) | | | | |
| METRICS | | ER (A/min) | ER (A/min) | ER (A/min) |
| PGMEA @ | 1 min | 1052 | >5166 | >5331 |
| 21° C. | 5 min | 181 | | |
| DI Water @ | 2 min | 518 | >2583 | >2666 |
| 21° C. | 1 min | 1030 | >5166 | >5331 |
| DI Water @ | 2 min | 595 | >2583 | >2666 |
| 50° C. | 1 min | 1011 | >5166 | >5331 |

ER = Etch Rate

Thus, specific embodiments and applications of sacrificial layers comprising water-soluble compounds, their uses and methods of production thereof have been disclosed. It should be apparent, however, to those skilled in the art that many more modifications besides those already described are possible without departing from the inventive concepts herein. Moreover, in interpreting the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A sacrificial composition, comprising:
at least one water-soluble compound, and
at least one solvent.

2. The sacrificial composition of claim 1, wherein the composition further comprises at least one water-soluble compound precursor.

3. The sacrificial composition of claim 1, wherein the at least one water-soluble compound comprises polyacrylamides and modified polyacrylamides, poly(acrylic acid), salts comprising poly(acrylic acid), poly(2-ethyl-2-oxazoline), polygalacturonic acid and salts thereof, poly(methacrylic acid) and salts thereof, poly(vinyl alcohol), alpha-cellulose, hydroxyethyl cellulose, N-vinylpyrrolidone/vinyl acetate copolymer and combinations thereof.

4. The sacrificial composition of claim 1, wherein the at least one solvent comprises water, ethanol, propanol, acetone, ethylene oxide, ethylene glycol, glycerol, lactic acid, dioxane, DMF, methylene chloride, THF, diluted acids, such as dilute aqueous sodium hydroxide, glycols, diethylenetriamine, DMAC, DMSO, ethylenediamine, formalin, formic acid, phenol, benzene, toluene, ethers, cyclohexanone, butyrolactone, methylethylketone, anisole and combinations thereof.

5. The sacrificial composition of claim 1, further comprising an absorbing compound or moiety.

6. The sacrificial composition of claim 1, further comprising a material modification agent.

7. A layer comprising the sacrificial composition of claim 1.

8. A film comprising the sacrificial composition of claim 1.

9. A hard mask or etch stop comprising the film of claim 8.

10. A via fill or planarization material comprising the layer of claim 7.

11. The layer of claim 7, wherein the sacrificial composition is at least partially removed by water.

12. The film of claim 8, wherein the sacrificial composition is at least partially removed by water.

13. A method of producing a sacrificial film, comprising:
providing at least one water-soluble compound and/or at least one water-soluble compound precursor,
providing at least one solvent; and
blending the at least one water-soluble compound with the at least one solvent to form the sacrificial composition.

14. The method of claim 13, wherein the composition further comprises at least one water-soluble compound precursor.

15. The method of claim 14, wherein the at least one water-soluble compound comprises polyacrylamides and modified polyacrylamides, poly(acrylic acid), salts comprising poly(acrylic acid), poly(2-ethyl-2-oxazoline), polygalacturonic acid and salts thereof, poly(methacrylic acid) and salts thereof, poly(vinyl alcohol), alpha-cellulose, hydroxyethyl cellulose, N-vinylpyrrolidone/vinyl acetate copolymer and combinations thereof.

16. The method of claim 13, wherein the at least one solvent comprises water, ethanol, propanol, acetone, ethylene oxide, ethylene glycol, glycerol, lactic acid, dioxane, DMF, methylene chloride, THF, diluted acids, such as dilute aqueous sodium hydroxide, glycols, diethylenetriamine, DMAC, DMSO, ethylenediamine, formalin, formic acid, phenol, benzene, toluene, ethers, cyclohexanone, butyrolactone, methylethylketone, anisole and combinations thereof.

17. The method of claim 13, further comprising an absorbing compound or moiety.

18. The method of claim 13, further comprising a material modification agent.

19. A layer comprising a sacrificial composition produced by the method of claim 13.

20. A film comprising a sacrificial composition produced by the method of claim 13.

21. A hard mask or etch stop comprising the film of claim 20.

22. A via fill or planarization material comprising the layer of claim 19.

23. The layer of claim 19 wherein the sacrificial composition is at least partially removed by water.

24. The film of claim 20, wherein the sacrificial composition is at least partially removed by water.
